(19) United States
(12) Patent Application Publication
(10) Pub. No.: US 2024/0425970 A1
(43) Pub. Date: Dec. 26, 2024

(54) VACUUM COATING APPARATUS, CONTROL DEVICE AND METHOD FOR INFLUENCING A RATE AT WHICH A COATING MATERIAL IS EMITTED

(71) Applicant: VON ARDENNE Asset GmbH & Co. KG, Dresden (DE)

(72) Inventor: Steffen MOSSHAMMER, Rabenau (DE)

(21) Appl. No.: 18/735,203

(22) Filed: Jun. 6, 2024

(30) Foreign Application Priority Data
Jun. 20, 2023 (DE) 10 2023 116 120.2

(51) Int. Cl. C23C 14/54

(52) U.S. Cl. CPC C23C 14/54

(57) ABSTRACT

Disclosed herein are devices, systems, and methods for coating a substrate. The method includes determining a data variable representing an actual state of a rate at which a coating material is emitted based on: a first response of a sensor before the sensor is exposed to the coating material and preferably heated thereby. The data variable is also determined based on a second response of the sensor after the sensor has been exposed to the coating material and preferably cools. The method also includes controlling a control element configured to affect the rate based on the data variable.

### CROSS-REFERENCE TO RELATED APPLICATION(S)

This application claims priority to German Patent Application No. 10 2023 116 120.2 filed on Jun. 20, 2023, the contents of which are incorporated fully herein by reference.

### TECHNICAL FIELD

This disclosure relates to a vacuum coating arrangement, a control device and a method for influencing a rate at which a coating material is emitted.

### BACKGROUND

In general, a vacuum coating arrangement may be used to coat one or more substrates. Coating may be carried out, for example, by chemical vapor deposition or by physical vapor deposition, e.g. within a vacuum chamber. The coating rate, i.e. the rate at which the one or more substrates are coated with a coating material, depends on a rate at which the coating material is emitted (from a coating device) (also referred to as the emission rate). The coating rate may therefore be a function of this emission rate. The emission rate may depend on various disturbance variables within the vacuum chamber, so that the emission rate may change over time. It may therefore be necessary to counteract a change in the state of the system caused by such disturbances. To make this possible, it may be necessary to determine or capture a current actual state of the rate (in-situ).

To determine the actual state of the rate (in-situ), a sensor such as an oscillating quartz (e.g. in combination with an associated oscillator) may be used, which is exposed to the emitted coating material. For example, a resonant frequency of the quartz oscillator changes depending on the mass of the coating material with which the sensor is coated. In this way, the magnitude of the frequency change per unit time may be used to infer the mass change per unit time and this mass change per unit time is then a measure of the rate at which the coating material is emitted.

According to various embodiments, it has been recognized that sensors in general, such as a vibrating quartz exposed to the coating material, have a limited lifetime due to the coating of the coating material. If the mass of the coating material with which the sensor (e.g. oscillating quartz) is coated reaches a sensor-specific threshold value, the function of the sensor may be impaired or even no longer fulfilled.

However, depending on the service life of the sensor, costs are not only incurred for a new sensor. As replacing the sensor at the end of its service life requires the coating process to be interrupted and/or the vacuum chamber to be opened, the service life of the sensor also limits the efficiency of the vacuum coating system. For example, this limits the service life (duration of uninterrupted production, also known as a campaign) of the vacuum coating system.

This wear or limitation of the service life is explained herein by way of example using an easily understandable oscillating quartz crystal as an exemplary rate sensor, whereby what is described for this may apply to any other sensor that is exposed to the coating material (e.g. during the measurement process), e.g. by means of which it is coated. By way of illustration, if a certain (e.g. average) rate at which the sensor is coated is assumed for a coating process (e.g. an average mass change per unit of time), the lifetime of the sensor may be represented by the accumulated measurement time (or operating time). This accumulated measurement duration may indicate an accumulated (maximum) total operating time for which the sensor is capable of capturing measurement data before its degradation causes it to no longer meet the requirements (thus reaching the end of its service life). Given a predefined period of time per individual measurement, this (maximum) total operating time results in a (maximum) number of individual measurements. Depending on the time intervals at which an individual measurement is carried out, this may result in a (maximum) service life of the vacuum coating system.

Usually a single measurement is performed while the sensor is coated with coating material. However, a response from the sensor may not only be a function of the change in mass, but also of the temperature of the sensor. Therefore, in a single measurement, it may be necessary to wait a predefined amount of time for the sensor to reach thermal equilibrium (e.g. an invariant temperature) before a response from the sensor is used to determine the rate. This may have a significant influence, for example, in vacuum coating arrangements in which comparatively high coating rates (e.g. for coating organic substrates) are used. Using the oscillating quartz crystal as an example, this predefined time period may be approximately 2 minutes. Consequently, this predefined time duration leads to a minimum measurement duration per individual measurement.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary aspects of the disclosure are described with reference to the following drawings, in which:

FIG. 1 shows a vacuum coating arrangement with a sensor for determining (and optionally influencing) a rate at which a coating material is emitted, according to various embodiments in a schematic top view or side view;

FIG. 2 shows an illustrative comparison of a measurement method according to the prior art and a measurement method according to various embodiments; and

FIG. 3 shows a diagram showing different phases of a time period in which a sensor is coated with coating material, according to different embodiments.

### SUMMARY

Various embodiments relate to a vacuum coating arrangement, a control device and a method which make it possible to determine (in-situ) an actual state of a coating process (e.g. the rate at which a coating material is emitted, also referred to as the emission rate) by means of a sensor in such a way that the service life of the vacuum coating arrangement is significantly increased. This is made possible by reducing the time required for a single measurement and/or for which the sensor is exposed to the coating material. Illustratively, the measurement process no longer (necessarily) takes place while the sensor is being coated with coating material, but before and after, so that a first response from the sensor is evaluated before the sensor is coated (and thereby heated) and a second response from the sensor is evaluated after the sensor has been coated. This means that it is no longer (necessarily) required to wait the predefined period of time until thermal equilibrium is reached in order to minimize the influence of temperature on the measurement process. As a result, the duration per individual measurement may be reduced by at least the predefined duration. Consequently, this leads to a significantly longer service life of the vacuum coating arrangement.

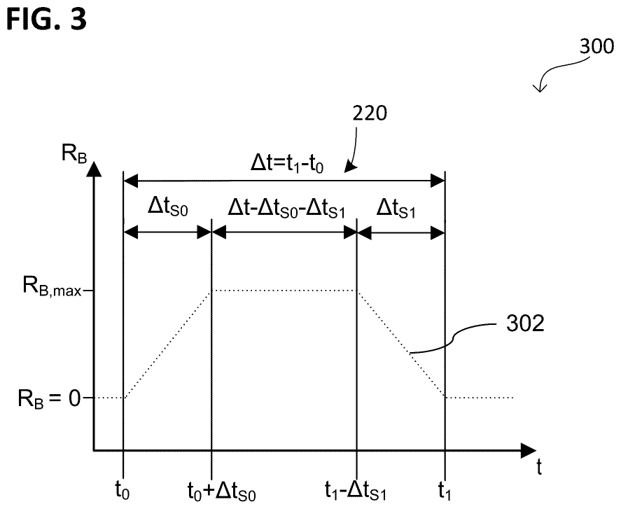

To illustrate this, a quartz oscillator may be considered as a sensor in a vacuum coating arrangement in which a coating material is emitted at a comparatively high rate. If, for example, a (maximum) total measurement duration of approximately 1 hour is assumed for the oscillating quartz, the predefined duration of approximately 2 minutes alone leads to a maximum number of 30 individual measurements. If each individual measurement is carried out at intervals of 10 minutes, this results in a (maximum) service life of the vacuum coating arrangement of 5 hours. Since it is not necessary to wait for the predefined period of time according to the present invention, the duration of the coating of the oscillating quartz may be 1 second (or less). With the same total measurement duration of 1 hour, this results in a maximum number of 3600 individual measurements and, with the time intervals of 10 minutes, a (maximum) service life of the vacuum coating arrangement of 25 days (instead of 5 hours). Taking into account the phases in which the rate at which the oscillating quartz is coated is lower (e.g. the phase in which a shutter is opened and/or the phase in which the shutter is closed), this service life is even longer (see, for example, FIG. 3).

As explained above, what is described herein for a quartz oscillator as an exemplary rate sensor may apply by analogy to any other type of sensor (e.g. rate sensor) which (e.g. during the measurement process) is exposed to the coating material, e.g. is coated by means thereof.

Various examples are described below that relate to what is described herein and shown in the figures.

Example 1 is a method comprising: determining a data variable representing an actual state of a rate (also referred to as an emission rate) at which a coating material is emitted or (more generally) a coating process (e.g., an operating parameter thereof) performed by means of the coating material, based on: a first response of a sensor before the sensor is exposed to the coating material and preferably heated thereby (e.g., by means of the coating material and/or by thermal radiation), and a second response of the sensor after the sensor has been exposed to the coating material and preferably cooled (e.g., thereby); and controlling a control element configured to influence the rate, or at least the coating process (e.g., the actual state, e.g., the operating parameter), based on the data variable.

Example 1a is a method comprising: determining a data variable representing an actual state of a process (e.g., coating process) performed, for example, by a coating material, based on: a first response of a sensor before the sensor is exposed to the process (e.g., the coating material thereof) and preferably heated thereby, and a second response of the sensor after the sensor has been exposed to the process (e.g., the coating material thereof) and preferably cools down; and controlling a control element configured to influence the process (e.g. coating process) based on the data variable.

Example 2 is a method comprising: determining an indication representing an actual state of a rate at which a coating material of a coating process is emitted based on: a first response of a sensor before the sensor is exposed to the coating material and preferably heated thereby, and a second response of the sensor after the sensor has been exposed to the coating material and preferably cools; and controlling a control element configured to influence the coating process (e.g., the rate) based on the indication.

Example 3 is configured according to example 1 or 2, wherein the determining of the data variable is further based on a time duration (e.g. a contiguous time interval) for which the sensor is exposed to the coating material (e.g. between the first response and the second response).

Example 4 is configured according to any one of examples 1 to 3, wherein the first response of the sensor occurs before the sensor is heated (e.g. by means of the coating material).

Example 5 is configured according to any one of examples 1 to 4, wherein the second response of the sensor occurs when the sensor cools down or after the sensor has cooled down.

Example 6 is configured according to any one of examples 1 to 5, wherein the sensor is not exposed to the coating material during the first response and/or the second response.

Example 7 is configured according to any one of examples 1 to 6, wherein the first response and/or the second response of the sensor is a function of a temperature of the sensor; and/or wherein a period of time (e.g., a contiguous time interval) for which the sensor is exposed to the coating material ends before the sensor has reached thermal equilibrium when the sensor is exposed to the coating material. For example, the time period may end while the temperature of the sensor (e.g. the quartz crystal thereof) changes (e.g. due to the thermal power supplied to the sensor by the coating material), e.g. increases.

Example 8 is configured according to any one of examples 1 to 7, wherein a (e.g. the) time duration for which the sensor is exposed to the coating material is less than or equal to 60 seconds, preferably less than or equal to 10 seconds, further preferably less than or equal to 500 milliseconds.

Example 9 is configured according to any one of examples 1 to 8, wherein the sensor comprises a quartz crystal which is exposed to (preferably coated by) the coating material.

Example 10 is configured according to any one of examples 1 to 9, wherein the sensor is coated by means of the coating material when exposed to the coating material.

Example 11 is configured according to any one of examples 1 to 10, wherein the first response and the second response are a function of a parameter (e.g. a resonant frequency) of the sensor (e.g. the quartz crystal) which is changed when the sensor is exposed to the coating material, wherein the parameter optionally further depends on a temperature of the sensor.

Example 12 is configured according to any one of examples 1 to 11, further comprising: capturing the first response of the sensor, preferably at the time before the beginning of the time duration (e.g. the continuous time interval); and/or capturing the second response of the sensor, preferably at the time after the end of the time duration (e.g. the continuous time interval).

Example 13 is configured according to any one of examples 1 to 12, further comprising: controlling a control element configured to influence a (e.g. the) time duration for which the sensor is exposed to the coating material (between the first response and the second response) and/or an amount of the coating material (also referred to as the amount of material) to which the sensor is exposed between the first response and the second response, e.g. according to a data variable representing a target state of the time duration and/or the amount, e.g. a mass flow of the coating material.

Example 14 is configured according to example 13, wherein the indication is further determined based on one or more than one additional data variable (e.g. comprising time dependence of mass flow rate, average value of mass flow, and/or switching time, etc.) over at least a portion of the time duration for which a mass flow (amount of material per time) of the coating material to which the sensor is exposed is time dependent.

Example 15 is configured according to example 14, wherein the at least one portion comprises or is at least a function of a switching time of a shutter; and/or wherein the mass flow is a function of a position of the shutter relative to the sensor.

Example 16 is configured according to example 15, wherein the at least one portion comprises a first portion which comprises a switching time for opening the shutter or is at least a function thereof, and a second portion which comprises a switching time for closing the shutter or is at least a function thereof; and/or wherein the at least one portion (e.g. the first portion and/or second portion) is a function of a speed at which the shutter is moved (e.g. rotated).

Example 17 is configured according to example 15 or 16, wherein the switching time of the shutter is less than or equal to one third of a time interval of the second response from the first response and/or one third of the time duration.

Example 18 is configured according to one of examples 13 to 17, wherein controlling of the control element is performed according to a (e.g. stored) target time duration (e.g. target switching time).

Example 19 is configured according to one of examples 1 to 18, if in combination with example 3 and/or 13, further comprising: capturing the duration of time for which the sensor is exposed to the coating material, preferably a duration of a switching (i.e. a switching time) of the shutter and/or preferably by means of one or more than one additional sensor.

Example 20 is configured according to any one of examples 1 to 19, wherein in determining the data variable further a time dependence of a mass flow of the coating material to which the sensor is exposed is taken into account; preferably the time dependence is taken into account as an average value of the time dependence of the mass flow.

Example 21 is configured according to any one of examples 1 to 20, if in combination with example 3 and/or 13, wherein the time period comprises: a first phase in which the sensor is moved into the emitted coating material (e.g. linearly, by means of rotation, etc.) or in which a (e.g. the) shutter is moved from a first state, in which the sensor is not exposed to the coating material, to a second state, in which the sensor is exposed to the coating material; and a second phase, in which the sensor is moved out of the emitted coating material or in which the shutter is moved from the second state to the first state.

Example 22 is configured according to example 21, wherein the data variable is further determined based on a duration of the first phase and/or a duration of the second phase.

Example 23 is configured according to any one of examples 1 to 22, wherein the sensor is not exposed to the coating material for a time interval until the second response (e.g., after the time interval).

Example 25 is a computer program configured, when executed by a processor, to cause the processor to perform the method according to any one of examples 1 to 23.

Example 25 is a computer readable medium with stored instructions configured, when executed by a processor, to cause the processor to perform the method according to any one of examples 1 to 23.

Example 26 is a control device comprising one or more than one processor configured to perform the method according to any one of examples 1 to 23.

Example 27 is a vacuum coating arrangement comprising: the control device according to example 26; a coating device for emitting the coating material; the control element for controlling the coating device; and the sensor.

Example 28 is configured according to example 27, wherein the coating device is configured to perform a chemical vapor deposition process and/or a physical vapor deposition process.

In example 29, the vacuum coating arrangement according to example 27 or 28 may optionally further comprise: a shutter configured such that the sensor is either exposed or not exposed to the coating material depending on a state of the shutter when the coating material is emitted by the coating device; and a driving device for adjusting the state of the shutter.

In example 30, the vacuum coating arrangement according to any one of examples 27 to 29 may optionally further comprise: a vacuum chamber in which the coating device and the sensor are arranged.

In example 31, the vacuum coating arrangement according to any one of examples 27 to 30 may optionally further comprise: the control element configured to influence the amount of time for which the sensor is exposed to the coating material between the first response and the second response and/or the amount of coating material to which the sensor is exposed between the first response and the second response.

### DESCRIPTION

Throughout the description, reference may be made to the accompanying drawings which form part thereof and in which specific embodiments in which the invention may be practiced are shown for illustrative purposes. In this regard, directional terminology such as “top”, “bottom”, “front”, “rear”, “forward”, “rearward”, etc. is used with reference to the orientation of the figure(s) described. Because components of embodiments may be positioned in a number of different orientations, the directional terminology is for illustrative purposes and is not limiting in any way. It is understood that other embodiments may be used and structural or logical changes may be made without departing from the scope of protection of the present invention. It is to be understood that the features of the various exemplary embodiments described herein may be combined with each other, unless specifically indicated otherwise. The following detailed description is therefore not to be construed in a limiting sense, and the scope of protection of the present invention is defined by the appended claims.

In the context of this description, the terms “connected”, “attached” and “coupled” are used to describe both a direct and an indirect connection (e.g. ohmic and/or electrically conductive, e.g. an electrically conductive connection), a direct or indirect connection and a direct or indirect coupling. In the figures, identical or similar elements are provided with identical reference signs where this is appropriate.

According to various embodiments, the term “coupled” or “coupling” may be understood in the sense of a (e.g. mechanical, hydrostatic, thermal and/or electrical), e.g. direct or indirect, connection and/or interaction. Several elements may, for example, be coupled together along an interaction chain along which the interaction may be exchanged, e.g. a fluid (then also referred to as fluid-conducting coupled). For example, two coupled elements may exchange an interaction with each other, e.g. a mechanical, hydrostatic, thermal and/or electrical interaction. A coupling of several vacuum components (e.g. valves, pumps, chambers, etc.) with each other may comprise that they are coupled with each other in a fluid-conducting manner. According to various embodiments, “coupled” may be understood in the sense of a mechanical (e.g. physical or physical) coupling, e.g. by means of a direct physical contact. A coupling may be configured to transmit a mechanical interaction (e.g. force, torque, etc.).

In connection with vacuum components (e.g. a pump, a chamber, a line, a valve, etc.), the term “coupled” or “coupling” may be understood in the sense of a connection to a common vacuum system. The components of the vacuum system may be configured to exchange a gas with each other by means of the coupling, whereby the coupling may be gas-separated from an exterior of the vacuum system.

The actual state of an entity (e.g. a device, a system or an operation or process) may be understood as the state of the entity that is actually present or may be detected by sensors. The target state of the entity may be understood as the desired state, i.e. a presetting. Control may be understood as an intended influence on the current state (also referred to as the actual state) of the entity. The current state may be changed in accordance with the presetting (also referred to as the target state), e.g. by changing one or more than one operating parameter (also referred to as the manipulated variable) of the entity, e.g. by means of a control element. Regulation may be understood as control, whereby a change of state is also counteracted by disturbances. For this purpose, the actual state is compared with the target state and the entity is influenced, e.g. by means of a control element, in such a way that the deviation of the actual state from the target state is minimized. In contrast to pure forward sequential control, closed-loop control thus implements a continuous influence of the output variable on the input variable, which is brought about by the so-called control loop (also referred to as feedback). In other words, this may be understood to mean that closed-loop control may be used as an alternative or in addition to open-loop control (or controlling) or that closed-loop control may be used as an alternative or in addition to closed-loop control.

The state of a controllable device (e.g. a structuring device) or a controllable process (e.g. structuring) may be specified as a point (also referred to as operating point or operating point) in a chamber (also referred to as state space) which is spanned by the variable parameters of the device or process (also referred to as operating parameters). The state of the device or process is thus a function of the respective value of one or more than one operating parameter, which thus represents the state of the device or process. The actual state may be determined based on a measurement (e.g. by means of a measuring element) of one or more than one operating parameter (then also referred to as a controlled variable).

The term “control device” may be understood as any type of logic-implementing entity that may comprise, for example, a circuit and/or a processor that may execute software stored in a storage medium, firmware, or a combination thereof, and issue instructions based thereon. The control device may, for example, be configured by means of code segments (e.g. software) to control the operation of a system (e.g. its operating point), e.g. a machine or a plant, e.g. at least its kinematic chain.

Control may be understood as the intentional influencing of a system. The current state of the system (also referred to as the actual state) may be changed in accordance with a presetting (also referred to as the target state). The parameters (also referred to as target parameters) of the target state explained herein may be or be implemented using code segments, for example, or may be or be stored in some other way on a storage medium. Regulation may be understood as control, whereby a change in the state of the system is also counteracted by disturbances. Illustratively, the control system may comprise a forward control path and thus illustratively implement a sequence control that converts an input variable (e.g. the presetting) into an output variable. However, the control path may also be part of a control loop so that closed-loop control is implemented. For control purposes, corresponding control elements of the system may be activated, which influence the actual state of the system. Examples of control elements comprising: a driving device (e.g. to provide a torque), a valve (e.g. to control a pressure), a switch (e.g. to close a discharge path). The driving device may, for example, comprise a linear drive (e.g. a reciprocating piston) or an electric motor.

If reference is made to a target parameter (e.g. a target rate at which a coating material is to be emitted), this may be implemented by means of code segments, which may be stored, for example, in a data memory associated with the control device. The code segments may be stored in the data memory in a suitable manner, for example as a list (e.g. table), a series of values, an algorithm, etc. A data store (more generally also referred to as a storage medium) may, for example, be a non-transitory data store. The data memory may, for example, comprise or be formed from a hard disk and/or at least one semiconductor memory (such as read-only memory, random access memory and/or flash memory). The read-only memory may, for example, be an erasable programmable read-only memory (may also be referred to as an EPROM). The random access memory may be a non-volatile random access memory (may also be referred to as NVRAM—“non-volatile random access memory”).

The term “control element” (e.g. comprising an actuator) may be understood as a converter configured to influence a state, a process (e.g. a coating process) or a device in response to controlling the control element. The control element may convert a control signal supplied to it (by means of which controlling takes place) into mechanical movements or changes in physical variables such as pressure or temperature. An electromechanical (also known as electromotive) control element may, for example, be configured to convert electrical power into mechanical power (e.g. through movement) in response to controlling. An electrothermal control element may, for example, be configured to convert electrical power into thermal power in response to controlling. An electrothermal control element may, for example, be configured to convert electrical power into thermal power in response to controlling. An electrical control element may, for example, be configured to convert electrical energy into electrical energy (e.g. certain voltage, current and/or power) in response to controlling.

A control element may be configured to influence the actual state (also referred to as the operating point) of the process (e.g. its manipulated variable), which is supplied by the control element. The influence may be direct or indirect. For example, the manipulated variable and controlled variable may differ from each other. The controlled variable (e.g. pressure) may then be a function of one or more than one manipulated variable (e.g. voltage).

For example, the control element may change an electrical voltage as a manipulated variable, by means of which a coating device for emitting coating material is supplied, so that as a result a rate at which the coating material is emitted and thus a coating rate (i.e. a rate at which a substrate is coated) or a layer thickness is changed as a controlled variable. For example, the control element may change an inflow rate of a gas as a manipulated variable, so that a pressure is changed as a controlled variable as a result.

Examples of components of a control element comprise: a coating device, a valve (e.g. of a pump arrangement and/or gas supply device, a motor (e.g. of a valve or pump), a circuit (e.g. for controlling the coating device), driving device (e.g. for controlling a state of a shutter) or the like. For example, the coating device may be configured to perform a coating process according to the controlling. The pump arrangement may, for example, be configured to pump out one or more than one gas in accordance with the controlling and thus remove it from the coating process. The gas supply device may, for example, be configured to supply one or more than one gas to the coating process in accordance with the controlling (also referred to as gas supply). The supplied gas may have a gas inflow rate (i.e. gas inflow per time). The gas inflow may, for example, be a standard volume flow supplied to the coating process.

With regard to the control of a control element, reference is made, among other things, to the more easily understandable control variable or its control value, which is influenced by the control element. What is described for this may apply by analogy to the control variable or its control value, which are fed to the control element for controlling, and vice versa. Illustratively, the control element acts as a converter that converts a control signal into the control variable or its control value, so that the control value is a function of the control value. Modern control elements are provided, for example, as a complex assembly comprising an actuator and a separate control device (also referred to as an actuator control device). The control element control device may be configured to receive the control value as an input by means of the control signal and to control the actuator according to the control value. The control variable is then generated and transmitted within the control element so that the control element is provided with the control variable. Less complex control elements may only process the control variable as a controlling signal, so that the control variable is fed to them for controlling.

More generally speaking, the controlling of a control element may be carried out by means of a control signal, whereby the control signal may represent the manipulated variable or its manipulated value and/or the control variable or its control value. Alternatively or additionally, the control signal may comprise instructions that specify how the manipulated variable or its manipulated value is to be changed (e.g. its relative change).

Controlling by the control device may be carried out according to an operating sequence. This operating sequence may be stored in the data memory in a suitable manner, for example as an algorithm or in another manner comprising code segments. As used herein, an operating sequence is understood to be a presetting according to which one or more than one control element-configured to influence a rate at which a coating material is emitted—is controlled. The operating sequence may specify one or more than one target parameter according to which the coating material is emitted at the rate.

A sensor (also referred to as a detector) may be understood as a converter that is configured to capture a property of its environment (e.g. qualitative or quantitative) corresponding to the sensor type as a measured variable, e.g. a physical property, a chemical property and/or a material property. The measured variable is the physical variable (also referred to as the controlled variable) to which the measurement by means of the sensor applies. Each sensor may be part of a measurement chain comprising a corresponding infrastructure (e.g. processor, storage medium and/or bus system and the like). The measuring chain may be configured to control the corresponding sensor, process its captured measured variable as an input variable and, based on this, provide an electrical signal as an output variable that represents the captured input variable. For example, the output variable may indicate the measured value. The measurement chain may be or be implemented by means of a so-called control device, for example. Various embodiments are directed to a sensor that is coated with a coating material, wherein the measured variable of the sensor may be a function of a mass of the coating material with which the sensor is or will be coated.

Herein the control and/or regulation of a coating process will be referred to, which may be carried out, for example, by controlling one or more than one control element (also referred to as positioning). In this context, reference is also made to a control device or code segments. The control device (also referred to as a control unit) may be configured to implement one or more than one of the methods (or at least one operation thereof) described herein. To this end, the control device may comprise a processor configured to implement the respective method. For example, the processor may be configured to output corresponding instructions for controlling. Alternatively or additionally, the processor may be configured to receive and process corresponding instructions and signals. The instructions received by the processor may, for example, be implemented using code segments that are stored in a non-transitory data memory. For example, the code segments may comprise at least instructions and/or one or more than one presetting which, when executed by the processor, cause the processor to perform one of the methods.

The term “processor” may be understood as any type of entity that allows the processing of data or signals. For example, the data or signals may be handled according to at least one (i.e. one or more than one) specific function performed by the processor. A processor may comprise or be formed from an analog circuit, a digital circuit, a mixed signal circuit, a logic circuit, a microprocessor, a central processing unit (CPU), a graphics processing unit (GPU), a digital signal processor (DSP), a programmable gate array (FPGA), an integrated circuit, or any combination thereof. Any other type of implementation of the respective functions, which are described in more detail below, may also be understood as a processor or logic circuit, for example also virtual processors (or a virtual machine) or a plurality of decentralized processors which are, for example, interconnected by means of a network, are distributed in any spatial manner and/or have any shares in the implementation of the respective functions (e.g. computational load sharing among the processors). The same generally applies to a differently implemented logic for implementing the respective functions. It will be understood that one or more of the method steps described in detail herein may be performed (e.g., realized) by a processor, through one or more specific functions performed by the processor.

With regard to the process of movement, e.g. the sensor, reference is made to the direction of movement. The direction of movement refers to the direction of the movement, e.g. the direction of a translation (then also referred to as the direction of translation) or a rotation (then also referred to as the direction of rotation). The translation may, for example, take place along a linear path of movement, e.g. in sections, which is parallel to the direction of translation (direction of translation). If the movement runs along a closed movement path that follows the direction of rotation, this is also referred to as a circular movement.

A driving device may be understood herein as a converter which is configured to convert (e.g. electrical) energy into mechanical energy. A driving device may, for example, comprise an electric motor (e.g. with electric coils). A driving device may, for example, comprise a compressor and a reciprocating piston coupled thereto. For example, a driving device may comprise one or more than one piezoelectric element. For example, the driving device may be configured to output the mechanical energy by means of a torque or a rotary movement.

The expression that an element, a parameter, etc. “represents” another element, another parameter, etc. may be understood to mean that the element or parameter is a (e.g. one-to-one) function of the other element or parameter.

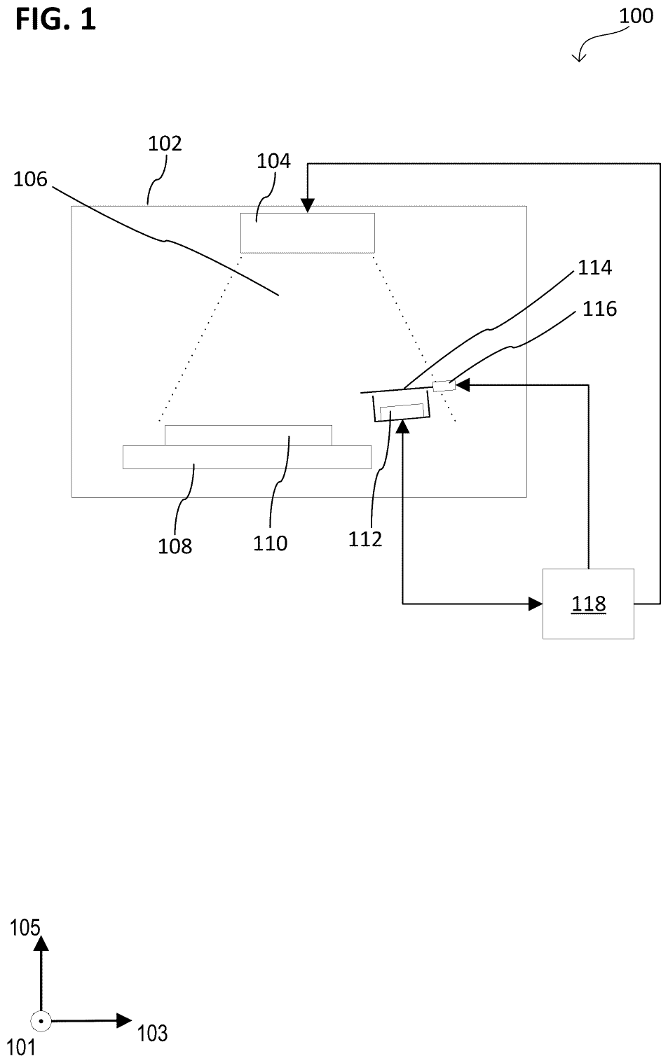

FIG. 1 illustrates a vacuum coating arrangement 100 according to various embodiments in a schematic top view or side view. The vacuum coating arrangement 100 may comprise a vacuum chamber 102. A vacuum chamber 102 may be or may be provided, for example, by means of a chamber housing in which one or more vacuum chambers may be provided. The chamber housing may, for example, be coupled to a pump arrangement, e.g. a vacuum pump arrangement, to provide a negative pressure or a vacuum (vacuum chamber housing) and may be configured in such a stable manner that it may withstand the action of the air pressure in the pumped-down state. The pump arrangement (comprising at least one vacuum pump, e.g. a high vacuum pump, e.g. a turbomolecular pump) may enable a portion of the gas to be pumped from the interior of the vacuum chamber 102. The or each vacuum chamber 102 may optionally comprise a chamber cover that seals the interior of the vacuum chamber 102 in a vacuum-tight manner. Accordingly, the plasma of the arc discharge may have a negative pressure (e.g., a vacuum).

The chamber housing, e.g., a vacuum chamber 102 provided therein, may be configured such that a negative pressure (i.e., a pressure of less than atmospheric pressure) may be provided therein, e.g., a vacuum (i.e., a pressure of less than 0.3 bar), e.g., a pressure in a region of about 10 mbar to about 1 mbar (in other words, rough vacuum) may be provided, or less pressure, e.g., a pressure in a region of about 1 mbar to about 10 mbar (in other words, fine vacuum) may be provided, or less pressure, e.g. a pressure in a region from about 10⁻³ mbar to about 10⁻⁷ mbar (in other words high vacuum), or less pressure, e.g. a pressure of less than high vacuum, e.g. less than about 10⁻⁷ mbar. The atmospheric pressure (e.g. 1 bar) may be the pressure acting on the chamber housing from the outside.

The vacuum coating arrangement 100 may comprise a coating device 104. The coating device 104 may be configured to emit a coating material. To this end, the coating device 104 may be any suitable type of coating device capable of emitting a coating material. According to various embodiments, the coating device 104 may be configured to perform a chemical vapor deposition process and/or a physical vapor deposition process. For example, the coating apparatus 104 may comprise a magnetron (a planar magnetron or a tubular magnetron). For example, the coating apparatus 104 may comprise an electron beam evaporator. For example, the coating device 104 may be configured to perform a spray coating or a spray coating process. For example, the coating apparatus 104 may comprise a nozzle tube evaporator for providing an evaporation source or multiple evaporation sources. It will be understood that these are exemplary embodiments of the coating device 104, and that it may have or be any other type of device for performing a chemical vapor deposition process and/or a physical vapor deposition process.

The respective gas pressure used to operate the coating device 104 (also referred to as operating pressure) and/or the respective gas or gas mixture supplied to the coating device 104 (also referred to as operating gas) may be highly application-dependent. For example, the operating pressure may be in a region from about 10⁻⁴ mbar (millibar) to about 5·10⁻⁴ mbar. For example, the operating gas may comprise one or more than one of the following gases: oxygen (e.g. molecular oxygen, i.e. O₂), nitrogen (e.g. molecular nitrogen, i.e. N₂), hydrogen (e.g. molecular hydrogen, i.e. H₂), one or more than one hydrocarbon compound, or a gas mixture thereof. The operating gas may comprise the working gas (e.g., an inert gas) and/or a reactive gas. The reactive gas may, for example, comprise hydrogen.

The coating device 104 may comprise a target. The target may generally comprise or consist of the coating material. The coating material emitted (e.g., released from the target) by the coating device 104 may form a stream of material 106 (e.g., away from the target).

During operation of the vacuum coating arrangement 100, one (or more than one) substrate 110 may be coated by means of the material stream 106. To this end, the vacuum coating arrangement 100 may comprise a substrate holder 108 configured to hold the one or more than one substrate 110. The substrate holder 108 may be disposed in the vacuum chamber 102. In some embodiments, the substrate holder 108 may be configured to be stationary. In other embodiments, the substrate holder 108 may be configured to be movable. For example, the vacuum coating arrangement 100 may be a continuous flow system comprising a transport system for transporting the substrate 110. In general, a continuous flow system may have two substrate transfer openings through which at least one substrate may be fed into and out of the continuous flow system. A plurality of processing areas may be configured between these two substrate transfer openings. For example, one or more of the processing areas may each comprise one or more than one coating device.

The or each substrate may generally comprise a workpiece, such as a semi-finished product (e.g. a rod, sleeve or plate) or a component of a more complex device. Examples of a substrate include: a piston ring, a bearing component, a tool, a chain, a drive chain, an obtuse-angled geometry; a knife, or a component sensitive to sliding friction. The or each substrate may, for example, be cylindrical, plate-shaped, or have another shape.

The or each substrate may comprise or be formed from at least one of the following: a ceramic, a glass, a semiconductor (e.g. amorphous, polycrystalline or single crystal semiconductor, such as silicon), a metal, and/or a polymer (e.g. plastic). The ceramic may, for example, comprise an oxide, a nitride and/or a carbide of a metal.

For the purposes of this description, a metal (also referred to as a metallic material) may comprise (or be formed from) at least one metallic element (i.e. one or more metallic elements), e.g. at least one element from the following group of elements: Copper (Cu), Iron (Fe), Titanium (Ti), Nickel (Ni), Silver (Ag), Chromium (Cr), Platinum (Pt), Gold (Au), Magnesium (Mg), Aluminum (Al), Zirconium (Zr), Tantalum (Ta), Molybdenum (Mo), Tungsten (W), Vanadium (V), Barium (Ba), Hafnium (Hf), Samarium (Sm), Silver (Ag), and/or Lithium (Li). For example, a metal may comprise or be formed from a metallic compound (e.g. an intermetallic compound or an alloy) or a compound of at least one metallic element (e.g. from the group of elements) and at least one non-metallic element (e.g. carbon), such as steel.

The vacuum coating arrangement 100 may comprise a control device 118. The control device 118 may be configured to control the coating device 104. For example, the control device 118 may control the coating device 104 according to one or more than one manipulated variable (e.g., an electrical voltage) to set a target rate at which the coating material is to be emitted as a controlled variable. The material flow 106 generated in this way may comprise an actual rate at which the coating material is emitted (i.e. an actual rate of the material flow 106). The actual rate of the material stream 106 may be a quantity of material per time (e.g. per time unit).

In operation, a portion of the material stream 106 may impinge on the substrate 110. Consequently, this portion of the material stream 106 may indicate an actual rate at which the substrate 110 is coated. This actual rate at which the substrate 110 is coated may also be referred to as the coating rate. As a result, the coating rate may be understood as an amount of the coating material that impinges on the substrate 110 per unit time, or an amount of the coating material that is deposited (deposited) on the substrate 110 per unit time. The coating rate may also be considered as a growth rate (coating thickness change per unit time) of a coating on the substrate 110. A quantity of material per time or time unit of the material flow 116 may also be referred to as mass flow and/or mass flow.

However, the actual rate of the material flow 106 may depend on various disturbance variables within the vacuum chamber 102, such as a temperature of the target, the pressure within the chamber, a gas flow of a supplied gas or gas mixture, etc.

It may therefore be necessary to control the rate at which the coating material is emitted. For this purpose, the control device 118 may be configured to control this rate based on the actual rate of the material flow 106 by means of the manipulated variable (e.g. the electrical voltage) in order to set the target rate as the controlled variable.

To this end, the vacuum coating arrangement 100 may comprise a sensor 112 (e.g., disposed in the vacuum chamber 102). The sensor 112 may be configured to provide a response that is a function of the mass of coating material with which the sensor is coated. Consequently, the sensor may be configured such that its response changes when the sensor is or becomes exposed to the coating material. An example of this is an oscillating quartz. In some embodiments, the sensor 112 may comprise the quartz crystal and an associated oscillator. In other embodiments, the control device 118 may comprise the associated oscillator. In the case of the oscillating crystal, the resonant frequency of the oscillating crystal changes as a function of the mass of the coating material with which the oscillating crystal is coated. This change in resonant frequency may be captured directly or indirectly. For example, the change in the resonant frequency may be captured indirectly by capturing a (frequency-dependent) impedance of the quartz crystal. When the resonant frequency of the quartz crystal is referred to here, it is understood that this resonant frequency is only formed (in operation) in the resonant circuit (i.e. after a corresponding signal is applied).

According to various aspects, the response of the sensor 112 may further be a function of a temperature of the sensor 112. As a result, the response of the sensor 112 may change as a function of the temperature of the sensor 112.

Reference is made herein in various illustrative examples to an oscillating crystal as sensor 112. It will be understood that this is for illustrative purposes, and that the sensor 112 may also comprise any other type of sensor in which a response of the sensor is a function of the mass of coating material with which the sensor is coated, and optionally further the temperature of the sensor.

According to various aspects, in operation, the sensor 112 may be exposed to the coating material, i.e., the material stream 106, for a period of time to determine the actual rate at which the coating material is emitted (or at least a data variable representing that actual rate). In some embodiments, the sensor 112 may be stationary within the vacuum chamber 102 and a shutter may be used to expose the sensor 112 to the material stream 106 or to block the material stream 106. In other embodiments, the sensor 112 may be moved into (and out of) the material stream 106 to be exposed thereto. For purposes of illustration, reference is made below to the embodiment with a shutter. It will be understood that the principle described herein may be applied accordingly to embodiments in which the sensor 112 is moved into the material stream 106.

The vacuum coating arrangement 100 may comprise a shutter 114 (also referred to as a shutter). The shutter 114 may be configured such that the sensor 112 is either exposed or not exposed to the coating material of the material stream 106, depending on a state of the shutter 114. For example, the shutter 114 may comprise at least a first state in which the sensor 112 is not exposed to the coating material (i.e., in which the material stream 106 is blocked) and at least a second state in which the sensor 112 is exposed to the coating material. The vacuum coating arrangement 100 may comprise a driving device 116 configured to adjust the state of the shutter 114.

Here, the shutter 114 may comprise any type of shutter by means of which the sensor 112 is either exposed or not exposed to the flow of material 106 depending on a state of the shutter. Accordingly, the driving device 116 may be any type of device by means of which a state of the shutter 114 may be changed. The control device 118 may be configured for controlling the driving device 116. As a result, the control device 118 may be configured to control a state of the shutter 114 (by means of the driving device 116). Therefore, the control device 118 may be configured to control a time duration for which the sensor 112 is exposed to the coating material (e.g., according to a target time duration).

In one example, the shutter 114 and the driving device 116, which is of a pneumatic type, may provide a pneumatic shutter system in which the state of the shutter 114 is dependent on whether or not compressed air is applied. In an advantageous embodiment, the shutter 114 may be a shutter that may be rotated by the driving device 116 from one of the at least one first state in which the sensor 112 is not exposed to the coating material (i.e., in which the material flow 106 is blocked) to one of the at least one second state in which the sensor 112 is exposed to the coating material, and vice versa. For example, the blocking orifice 114 may be an orifice comprising two first states and two second states. In this case, for example, a quarter turn of the shutter 114 driven by the driving device 116 may be made from one first state to the second state, a subsequent quarter turn of the shutter 114 may be used to rotate the shutter 1114 from the second state to the other first state, and another subsequent quarter turn of the shutter 114 may then be used to rotate the shutter 1114 from the other first state to the other second state. As a result, the shutter 114 may be rotatably attached. For example, the shutter 114 may have a diameter in a region of about 50 mm to about 300 mm (e.g., about 100 mm). According to various embodiments, the driving device 116 may be or comprise a stepper motor. It will be understood that this is an exemplary embodiment of the shutter 114 and is provided by way of illustration. The embodiment in which the shutter 114 is rotatably attached with the at least one first state and the at least one second state, and in which the driving device 116 comprises a stepper motor, may be advantageous over pneumatic shutter systems due to a reduced switching time, as this allows for a significantly reduced duration of a single measurement. For example, in one embodiment, the rotatably attached shutter 114 may be a rotatably mounted disk. In another embodiment, the rotatably attached shutter 114 may comprise or be a revolving element (e.g., a band and/or wheel). This circumferential member may comprise one or more openings, such that an opening may provide a corresponding second condition in which the sensor 112 may be exposed to the coating material.

As an alternative to the rotatably attached mounting, the shutter panel may, for example, be attached so that it may be moved in translation.

It may be understood that what is described herein as an example of the operation of the shutter may apply by analogy to any other type of implementation of a measurement sequence (repeated several times) comprising a first phase in which the sensor is exposed to the coating process for the period 220 and a second phase in which the sensor is shielded from the coating process for an additional period of time (also referred to as a measurement pause). For example, the measurement sequence may be implemented using a shutter that is moved relative to the source of the coating material (translationally or rotationally) relative to a sensor that is stationary relative to the source of the coating material. For example, the measurement sequence may be implemented by means of a support on which the sensor is mounted and which is stationary (translationally or rotationally) relative to the source of the coating material. For example, the movement of several shutters may be superposed in order to implement the shortest possible time 220. For example, instead of one shutter aperture, several shutter apertures of different geometry may be used to change the time duration 220.

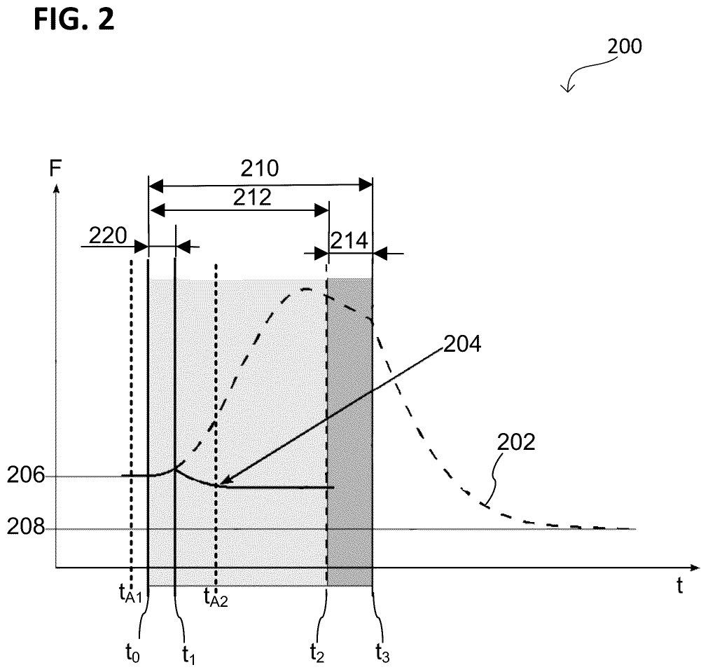

FIG. 2 shows an illustrative comparison of a measurement method according to the prior art and a measurement method according to various embodiments. This exemplary illustration relates to a sensor 112 comprising a resonant crystal, and therefore diagram 200 shows a (resonant) frequency, F, of the resonant crystal as a function of time, t. It will be understood that the oscillating crystal is an example of the sensor 112 and that in the case of another sensor, a parameter different from the frequency may be captured. Also, the frequency, F, of the oscillating crystal is merely an exemplary parameter for the oscillating crystal. In other embodiments, a (frequency-dependent) impedance of the oscillating quartz may be captured as a parameter.

Diagram 200 shows a first frequency response 202 according to the prior art. Here, the shutter 114 may initially (i.e. before time to) be in the first state in which the sensor 112 is not exposed to the coating material (i.e. in which the material flow 106 is blocked) and a response from the sensor 112 may have an output frequency 206. At time to, the shutter 114 may be opened and the sensor 112 may thus be exposed to the coating material. The resulting change in mass of the coating material deposited on the sensor 112 may lead to a reduction in the frequency, F. The energy input from the coating material may heat the sensor 112. As described herein, the response of the sensor 112, i.e., the frequency F in this example, may be a function of the temperature of the sensor 112. The increase in temperature may result in an increase in frequency, F. This may result in the decrease in frequency, F, caused by the change in mass not being captured. This increasing frequency is illustratively shown in diagram 200. For this reason, it may be necessary to wait a predefined period of time 212 (from time t₀ to time t₂) until the sensor 112 has reached thermal equilibrium (see light gray region). This predefined time period may also be regarded as a dead time, as the response of the sensor cannot be used to determine the rate during this time. Then, in a subsequent measurement interval 214 (from time t₂ to time t₃), a frequency change over time may be captured as a measure of the mass change over time (see dark gray region). At time t₃ the shutter 114 may then be closed in order to no longer expose the sensor 112 to the coating material so that it cools down. After the sensor 112 has cooled, it may have a reduced final frequency 208 due to the change in mass (compared to the output frequency 206), although this is conventionally no longer captured. As described herein, the predefined time duration 212 may be several minutes. Thus, the measurement duration 210 for a single measurement may require at least these several minutes.

Diagram 200 also shows a second frequency response 204 according to various embodiments. Here, a first response of the sensor 112 may be captured at a time t_{A1}, which is before the time to. For example, the control device 118 may be configured to trigger the sensor 112 at time t_{A1} to capture the first response. Thus, the first response may be captured while the shutter 114 is closed and thus the sensor 112 is not exposed to the coating material. Consequently, the first response may be captured before the sensor 112 is heated (e.g. by means of the coating material).

The control device 118 may be configured to control the driving device 116 in order to open the shutter 114 at the time to and thus expose the sensor 112 to the coating material. This may cause the sensor 112 to heat up. According to various embodiments, the control device 118 may be configured to control the driving device 116 to close the shutter 114 at time t₁ (or the closing may be completed at time t₁, see FIG. 3) and thus no longer expose the sensor 112 to the coating material. The sensor 112 may then cool down.

According to various embodiments, the control device 118 may be configured to trigger the sensor 112 at the time t_{A2} to capture a second response from the sensor 112. The time t_{A2} may be after the time t₂. As a result, the second response may also be captured while the shutter 114 is closed and the sensor 112 is thus not exposed to the coating material. Here, the second response may be captured after the sensor 112 has been exposed to the coating material. Accordingly, the sensor 112 may be exposed to the coating material for a period of time 220. In principle, any period of time may elapse between the time t₂ and the capture of the second response at the time t_{A2} as long as the shutter 114 remains closed.

The control device 118 may be configured to capture the change in mass based on the first response and the second response (e.g., based on the difference between a frequency 206 associated with the first response and a frequency associated with the second response). The control device 118 may be configured to determine a mass change per time based on the mass change and the time duration 220 for which the sensor 112 is exposed to the coating material. The control device 118 may be configured to determine, based on the mass change per time, a data variable representing the actual state of the rate at which the coating material is emitted.

The control device 118 may be configured to control the driving device 116 according to a (e.g., stored) target time duration for which the sensor 112 is to be exposed to the coating material. In some embodiments, the control device 118 may be configured to determine the data variable about the actual state of the rate based on this target time duration. In other embodiments, the vacuum coating arrangement 100 may comprise one or more than one additional sensor to capture the time to and/or the time t₁. In this case, the control device 118 may be configured to determine the time duration 220 as the time difference of these captured time points.

The control device 118 may be configured for controlling the coating device 104 in order to regulate the coating process, for example in such a way that a deviation between the actual state of the rate and the target state of the rate is reduced.

Since the first response and the second response are captured while the shutter 114 is closed and the sensor 112 is therefore not coated, it is no longer necessary to wait for the predefined time duration 212 compared to the prior art measurement method. Accordingly, the period of time for which the sensor 112 is exposed to the coating material (also referred to as the coating duration) may end before the sensor 112 has reached thermal equilibrium. In this manner, the coating duration may be significantly reduced. For example, the period of time 220 for which the sensor 112 is exposed to the coating material may be less than or equal to 60 seconds (e.g., less than or equal to 30 seconds, e.g., less than or equal to 10 seconds, etc.).

The reduced time 220 for which the sensor 112 is exposed to the coating material also results in a lower temperature rise of the sensor 112 due to the energy introduced by means of the coating material, thereby improving adhesion of the coating material to the sensor 112 (and thus reducing particle formation and re-evaporation of material deposited on the sensor 112) and further increasing the service life of the vacuum coating assembly 100.

According to various aspects, the duration 220 for which the sensor 112 is exposed to the coating material may be less than or equal to 1 second (e.g., less than or equal to 500 milliseconds, e.g., less than or equal to 100 milliseconds). However, in this case, a duration of a switching (i.e., a switching time) of the shutter 114 from one state to another state may have a relevant influence on determining the rate.

The switching time refers to the time it takes to bring the shutter 114 from a closed state (in which the sensor is shielded from the coating material) to an open state (in which the sensor is exposed to the coating material) or vice versa. Illustratively, the opening or closing of the shutter 114 may take a certain amount of time (the so-called switching time) and during this time the rate may be time-dependent. Thus, the rate at which sensor 112 is coated may be time-dependent (and decreased) for a time duration of an opening of shutter 114 (also referred to as an opening time duration) and/or a time duration of a closing of shutter 114 (also referred to as a closing time duration). According to various embodiments, the control device 118 may be configured to take this time dependency of the rate at which sensor 112 is coated into account when determining the data variable. It will be understood that the opening and closing of the shutter 114 is exemplary. For example, if the sensor 112 is moved into and then out of the material stream 106, the rate at which the sensor 112 is coated may be time-dependent for a period of time of moving into the material stream 106 and for a period of time of moving out of the material stream 106.

FIG. 3 shows a diagram 300 with different phases of the time duration 220 according to various embodiments. Herein, reference is made to an easily understandable notation with respect to the time duration 220 in the form of a time difference (Δt) between the time t₁ and the time to, it being understood that what is described herein may apply by analogy to any other notation of the time duration 220. The diagram 300 shows the rate, R_{B}, at which the sensor 112 is coated.

In some embodiments, the time to may be substantially the time at which the control device 118 controls the driving device 116 to open the shutter 114. In other embodiments, the vacuum coating arrangement 100 may comprise at least a first additional sensor configured to capture a start of the opening of the shutter 114 as the time to.

According to various embodiments, the vacuum coating arrangement 100 may comprise at least one second additional sensor. The at least one second additional sensor may be configured to capture a time t₀+Δt_{S0} at which the shutter 114 is fully open. The time difference between the start of the opening process and the end of the opening process is the opening time duration Δt_{S0}.

According to various embodiments, a time t₁−Δt_{S1} at which the closing process begins and/or the time t₁ at which the closing process ends (i.e. is completed) may be captured accordingly by means of the at least one first additional sensor and/or the at least one second additional sensor. The time difference between the start of the closing process and the end of the closing process is the closing time duration Δt_{S1}.

In the phase (from the time t₀+Δt_{S0} to the time t₁−Δt_{S1}) between the opening operation and the closing operation, the rate, R_{B}, may saturate at a maximum rate, R_{B,max}. According to various aspects, the time duration 220 may be selected such that the phase (from the time t₀+Δt_{S0} to the time t₁−Δt_{S1}) between the opening operation and the closing operation is at least one third of the time duration 220. It will be understood that the smaller the opening time duration Δt_{S0} and the closing time duration Δt_{S1} are, the smaller the time duration 220 may be (and the longer the service life of the vacuum coating arrangement 100 will be). According to various aspects, the timing may be measured with a timing accuracy of at least 0.1%. According to various embodiments, the time duration 220 (i.e. the time difference Δt between the time t₁ and the time t₀) may comprise the opening time duration Δt_{S0} and the closing time duration Δt_{S1} (i.e. Δt=Δt_{S0}+Δt_{S1}). As a result, the time duration 220 in this case cannot have a time interval between the opening process and the closing process (i.e. Δt−Δt_{S0}−Δt_{S1}=0). If Δt=Δt_{S0}+Δt_{S1}, the measuring sequence may be configured as a continuous process (of opening and closing).

The control device 118 may be configured to determine the data variable of the actual state of the rate at which the coating material is emitted using the time dependence of the opening and closing in conjunction with the opening time duration Δt_{S0} and the closing time duration Δt_{S1}.

According to various embodiments, the shutter 114 and the driving device 116 may be configured such that a speed at which the shutter 114 is moved from one state (e.g., closed state or open state) to the other state (e.g., open state or closed state) is substantially constant. For example, as explained above, the shutter 114 may be rotatably attached and the driving device 116 may comprise the stepper motor. The substantially constant switching speed (i.e. the speed at which switching from one state to the other occurs) means that a change in the rate R_{B} at which the sensor 112 is coated is substantially constant. In this case, the rate R_{B}, at which the sensor 112 is coated, corresponds approximately to half the maximum rate, R_{B,max}, for the opening time duration Δt_{S0} and the opening time duration Δt_{S1}.

According to various embodiments, the control device 118 may be configured to determine the data variable of the actual state of the rate at which the coating material is emitted using the (e.g. captured) open time duration Δt_{S0} and the (e.g. captured) close time duration Δt._{S1}.

In some embodiments, the control device 118 may be configured to determine the data variable of the actual state of the rate at which the coating material is emitted using a predefined (e.g. stored) (opening and/or closing) switching time. In this case, the at least one second additional sensor is optional. In this case, the time to may essentially be the time at which the control device 118 activates the driving device 116 to open the shutter 114, the time t₀+Δt_{S0} may be determined using the (e.g. stored) predefined opening time, Δt_{S0}, the time t₁−Δt_{S1} may essentially be the time at which the control device 118 controls the driving device 116 to close the shutter 114, and the time t₁ may be determined using the (e.g. stored) predefined closing time Δt_{S1}. As an alternative to the predefined (e.g. stored) (opening and/or closing) switching time, the control device 118 may be configured to determine the switching time based on a predefined (e.g. stored) switching speed.

Illustratively, this comparison of the measurement method described herein with the measurement method according to the prior art shows that the coating time (i.e. the time in which the sensor (e.g. the oscillating quartz) is coated) may be significantly reduced compared to the prior art (since no waiting for thermal equilibrium is required). This leads to an increased service life of the vacuum coating arrangement by several dimensions.

Examples of the data variable explained herein, representing an actual state of a rate (also referred to as an emission rate) at which a coating material is emitted, include:
a (e.g. time-averaged) mass flow of the coating material,
a rate at which the sensor is coated with the coating material,
a quantity of the coating material with which the sensor is coated within the time period;
a frequency of the sensor, e.g. the oscillating quartz crystal thereof; and
a time until the sensor is coated with a target quantity of the coating material.

It may be understood that what is described herein for the emission rate captured by the sensor may apply by analogy to any other operating parameter (e.g., of a process, e.g., coating process) captured by a sensor whose output and/or mode of operation is dependent on, for example, a disturbance variable that is, for example, a function of time and/or temperature of the sensor.

1. A method comprising:
determining a data variable representing an actual state of a rate at which a coating material is emitted based on:
a first response of a sensor before the sensor is exposed to the coating material, and
a second response of the sensor after the sensor has been exposed to the coating material; and
controlling a control element configured to influence the rate based on the data variable.

2. The method according to claim 1, wherein the determining of the data variable is further based on a time duration for which the sensor is exposed to the coating material.

3. The method according to claim 1, wherein the first response of the sensor occurs before the sensor is heated and/or wherein the second response of the sensor occurs when the sensor cools down or after the sensor has cooled down.

4. The method according to claim 1, wherein the sensor is not exposed to the coating material during the first response and/or the second response.

5. The method according to claim 1, wherein the first response and/or the second response of the sensor are a function of a temperature of the sensor.

6. The method according to claim 1, wherein a time period for which the sensor is exposed to the coating material:
is less than or equal to 60 seconds; and
ends before the sensor, which is exposed to the coating material, has reached thermal equilibrium.

7. The method according to claim 6, wherein the time period for which the sensor is exposed to the coating material is less than or equal to 10 seconds.

8. The method according to claim 1, wherein the sensor comprises a quartz crystal which is exposed to the coating material.

9. The method according to claim 1, further comprising:
controlling a control element configured to influence a time duration for which the sensor is exposed to the coating material and/or an amount of the coating material to which the sensor is exposed between the first response and the second response.

10. The method according to claim 9, wherein the data variable is further determined based on an additional data variable of at least a portion of the time duration for which a mass flow of the coating material to which the sensor is exposed is time-dependent.

11. The method according to claim 10, wherein the at least one portion comprises a switching time of a shutter or is at least a function thereof and/or wherein the mass flow is a function of a position of the shutter relative to the sensor.

12. The method according to claim 1, wherein a time dependence of a mass flow of the coating material to which the sensor is exposed is further taken into account when determining the data variable, wherein the time dependence is a mean value of the time dependence of the mass flow.

13. The method according to claim 1, wherein the first response of the sensor is before the sensor is heated by being exposed to the coating material.

14. The method according to claim 1, wherein the second response of the sensor is after the sensor has cooled down.

15. A computer readable medium comprising instructions that are configured, when executed by a processor, to cause the processor to:
determine a data variable representing an actual state of a rate at which a coating material is emitted, wherein the data variable is based on:
a first response of a sensor before the sensor is exposed to the coating material and heated thereby, and
a second response of the sensor after the sensor has been exposed to the coating material and cools down; and
control a control element configured to influence the rate based on the data variable.

16. A vacuum coating assembly comprising:
a sensor;
a control device configured to:
determine a data variable representing an actual state of a rate at which a coating material is emitted, wherein the data variable is based on a first response of the sensor before the sensor is exposed to the coating material and based on a second response of the sensor after the sensor has been exposed to the coating material; and
control a control element configured to influence the rate based on the data variable; and
a coating device for emitting the coating material according to the control element.

17. The vacuum coating assembly according to claim 16, wherein the control device is configured to determine the data variable further based on a time duration for which the sensor is exposed to the coating material.

18. The vacuum coating assembly according to claim 16, wherein the control device is configured to determine the first response of the sensor before the sensor is heated.

19. The vacuum coating assembly according to claim 16, wherein the control device is configured to determine the second response of the sensor while the sensor cools down or after the sensor has cooled down.
